(19) United States
(12) Patent Application Publication
(10) Pub. No.: US 2003/0173870 A1
(43) Pub. Date: Sep. 18, 2003

(54) Piezoelectric ultrasound transducer assembly having internal electrodes for bandwidth enhancement and mode suppression

(76) Inventor: Shuh-Yueh Simon Hsu, Mercer Island, WA (US)

Correspondence Address: Steven H. Arterberry, Esq., DORSEY & WHITNEY LLP, Suite 3400, 1420 Fifth Avenue, Seattle, WA, 98101, US

(21) Appl. No.: 10/096,720

(22) Filed: Mar. 12, 2002

(51) Int. Cl. H01L 41/04

(52) U.S. Cl. 310/334

(57) ABSTRACT

An apparatus and method for transmitting ultrasound energy having extended bandwidth and/or suppressed spurious modes for ultrasound transducers is disclosed. In one embodiment, an ultrasound imaging system includes a system chassis for generating ultrasound signals and a transducer assembly coupled to the system chassis having a plurality of stacks each comprised of a plurality of piezoelectric layers having one or more intermediate electrodes interposed between the piezoelectric layers. The assembly further includes a first electrode positioned on a first end of each stack, and a second electrode is positioned on an opposing second end, the first and second electrodes being coupled to the system chassis of the ultrasound imaging system and the intermediate electrodes being coupled to the first or second electrodes.

### TECHNICAL FIELD

This invention relates generally to ultrasound imaging systems that use ultrasonic transducers to provide diagnostic information concerning the interior of the body, and more particularly, to an apparatus and method for transmitting ultrasound energy having enhanced bandwidth and/or lower spurious vibration modes.

### BACKGROUND OF THE INVENTION

Ultrasonic diagnostic imaging systems are in widespread use for performing ultrasonic imaging and measurements. For example, cardiologists, radiologists, and obstetricians use ultrasonic imaging systems to examine the heart, various abdominal organs, or a developing fetus, respectively. Diagnostic images are obtained from these systems by placing a transducer assembly against the skin of a patient, and actuating one or more piezoelectric elements located within the transducer assembly to transmit ultrasonic energy through the skin and into the body of the patient. In response, ultrasonic echoes are reflected from the interior structure of the body, and the returning acoustic echoes are converted into electrical signals by the piezoelectric elements in the transducer assembly.

FIG. 1 is an isometric view of a typical diagnostic ultrasound imaging system 1. The diagnostic ultrasound imaging system 1 includes an ultrasound transducer assembly 10 that is adapted to be placed in contact with a portion of a body that is to be imaged. The transducer assembly 10 is coupled to a system chassis 3 by a cable 4. The system chassis 3 further includes a signal source (not shown) capable of generating time-varying signals at ultrasound frequencies, as well as other electronic devices, such as a processor (also not shown) capable of processing the acoustic energy received by the transducer assembly 10 to produce a visual image. The system chassis 3, which is mounted on a cart 5, includes a keyboard 6 by which data may be entered into the processor included in the system chassis 3. A display monitor 7 having a viewing screen 8 is placed on an upper surface of the system chassis 3 to view the visual image produced by the system chassis.

FIG. 2 is a partial isometric view of the transducer assembly 10 that will be used to describe the assembly 10 in greater detail. The transducer assembly 10 includes a plurality of piezoelectric elements 11 that extend in an azimuthal direction 1 to form a repetitive linear array of the elements 11. Alternatively, more than a single row of the elements 11 may be present to form a rectangular array of the elements 11 that extends in both an azimuthal direction 1 and an elevation direction 2. In either case, the transducer assembly 10 also includes a plurality of first electrodes 12 that are coupled to a lower surface of each element 11, and a plurality of second electrodes 13 that are coupled to an opposing upper surface of each of the elements 11. The first electrodes 12 and the second electrodes 13 are coupled to an ultrasound system (as shown in FIG. 1) that generates a time-varying signal to produce ultrasonic waves that propagate outwardly from the assembly 10 in a range direction 3 and into the body of a patient. The time-varying signal generated by the ultrasound system may be coupled to the first electrodes 12 through a flex circuit 14, although other connection means may be used. The second electrodes 13 may also be coupled to the ultrasound system by a flex circuit 15, which is similar in configuration to the flex circuit 14. Ultrasonic waves reflected from interior structures of the body of the patient are received by the elements 11 and correspondingly generate time-varying signals that may be transferred to the ultrasound system through the flex circuits 14 and the flex circuit 15 to be further processed to produce a visual image of the interior structures. The use of a plurality of separate elements 11 in the transducer 10 allows each element 11 to be selectively controlled and excited so that the ultrasonic waves transmitted from the transducer assembly 10 may be combined to produce a net ultrasonic wave focused at a selected point within the patient's body. In a similar manner, reflected ultrasonic waves received by each of the elements 11 in the transducer assembly 10 may be selectively time-delayed and summed to produce a net output signal that is dominated by waves reflected from a selected point in the patient's body. Still referring to FIG. 2, the transducer assembly 10 further includes an acoustic backing member 16 that is positioned below the first electrodes 12 to substantially attenuate acoustic signals propagated from the lower surfaces of the elements 11. The backing member 16 is generally comprised of a material having relatively high acoustic attenuation that also provides a relatively rigid support for the elements 11 and the electrodes 12 and 13. The transducer assembly 10 may optionally include one or more impedance matching layers 17 that are generally positioned on the second electrodes 13 to permit the elements 11 to more closely match the acoustic characteristics of the patient's body.

One phenomenon present in ultrasonic diagnostic imaging is that the fluids and tissues comprising the body of the patient have a significant non-linear acoustic response when exposed to ultrasound energy. As a result, harmonic reflections are often generated within the body at one or more frequencies that are harmonically related to a fundamental transmit frequency. In one known application of this phenomenon, various contrast agents may be introduced into selected tissues or the bloodstream of the patient to produce an enhanced non-linear acoustic response. The enhanced response permits selected regions of interest in the patient's body to be further highlighted and differentiated from other surrounding tissues.

With reference still to FIG. 2, the transducer assembly 10 is generally configured to be operable within a predetermined bandwidth that includes a range of frequencies centered about a fundamental transmit frequency. As a consequence, the assembly 10 exhibits favorable sensitivity at frequencies that are close to the fundamental frequency, but generally less sensitivity to frequencies near the edges of the bandwidth. Since harmonic reflections of interest often occur at frequencies near the edge of the transducer bandwidth, the sensitivity of transducer assembly 10 to these frequencies is often substantially reduced. This problem is particularly acute in cases where the desired reflected wave is necessarily of small magnitude. For example, the aforementioned contrast agents may be introduced into a relatively small bodily portion, such as a blood vessel, in order to produce diagnostic information concerning the blood flow in the vessel. Since the area to be imaged is relatively small, only relatively weak harmonic reflections are returned to the assembly 10 for detection. It would be desirable, therefore, to have a transducer assembly that permits the transmission of ultrasound waves and the detection of reflected ultrasound waves with greater sensitivity than is attainable with the prior art transducer assembly 10.

In an attempt to address the foregoing bandwidth issue, the prior art has described two general approaches to broaden the transducer frequency response. One approach is to optimize the design of passive layers, including multiple matching and backing layers, for broader single passband or dual passband frequency response. Transducers using this approach generally have the same frequency response for the transmit mode as well as for the receive mode, and the ultrasound system is used to select a desirable frequency response by altering the transmit waveform, alternating the receive filter, or both. In practical transducers, the number of passive layers which can be assembled is very limited. Therefore, this approach can only achieve limited bandwidth improvement without compromising other performance parameters such as sensitivity. The second approach is to optimize the design of the active layer, which in most cases is made of piezoelectric material. Efforts on active layer optimization generally fall into two categories. The first category is to prepare the piezoelectric layer material with variable thickness along the elevation direction, thus broadening the frequency response of the transducer element. This concept has been described in publications (e.g., “Dual frequency piezoelectric transducer for medical applications,” M. S. S. Bolorforosh, SPIE Vol. 1733, (1992) at pp. 131 et seq.) and patents (e.g., U.S. Pat. No. 5,415,175, Hanafy et al.). The second category of active layer design is to construct transducer elements with multiple layers of active transducer materials, and use a switching circuit to control the polarity of each layer or the signal applied to each layer, thus generating different frequency responses of the transducer elements during transmit and receive. For example, U.S. Pat. No. 5,410,205 (Gururaja) proposes a transducer stack consisting of 2 or more electrostrictive layers. By selectively applying bias voltage to each layer, the transducer can be selected to transmit at one resonance frequency and receive at another resonance frequency. U.S. Pat. No. 5,825,117 (Ossmann) and U.S. Pat. No. 5,957,851 (Hossack) also propose transducer stacks consisting of 2 piezoelectric layers. Switching circuits are attached to each transducer element so that different frequency responses can be generated during the transmit and receive modes. A drawback of this approach is the requirement of an additional control electronic circuit associated with each transducer element, thus adding to the complexity of the transducer assembly.

### SUMMARY OF THE INVENTION

This invention relates generally to an apparatus and method for increasing the bandwidth and/or suppressing spurious vibration modes of ultrasound transducers. In one aspect of the invention, an ultrasound imaging system includes a system chassis for generating ultrasound signals and a transducer assembly coupled to the system chassis having a plurality of stacks each comprised of a plurality of piezoelectric elements having a plurality of intermediate electrodes interposed between the piezoelectric elements. The assembly further includes a first electrode positioned on a first end of each stack, and a second electrode is positioned on an opposing second end, the first, second and intermediate electrodes being coupled to the system chassis of the ultrasound imaging system. In one illustrated embodiment of the invention the transducer elements consist of multiple layers of non-matching or backing materials, and at least one of the layer materials is active material. No switching or control circuit is necessary. Depending on the thickness of each layer and how the signal and ground paths are connected, the stack can be used to generate both fundamental and harmonic responses or used to suppress unwanted spurious modes, or both.

### BRIEF DESCRIPTION OF THE DRAWINGS

FIG. 1 is an isometric view of an ultrasound diagnostic imaging system according to the prior art.

FIG. 2 is a partial isometric view of a transducer assembly according to the prior art.

FIG. 3 is a partial isometric view of a transducer assembly according to an embodiment of the invention.

FIG. 4 is a partial cross-sectional plan view of a transducer assembly according to an embodiment of the invention.

FIG. 5 is a graph illustrating the frequency response characteristics of a transducer assembly according to an embodiment of the invention.

FIG. 6 is a graph illustrating the signal response bandwidth characteristics of a transducer assembly according to an embodiment of the invention.

FIG. 7 is a partial isometric view of a transducer assembly according to another embodiment of the invention.

FIG. 8 is a partial cross-sectional plan view of a transducer assembly according to another embodiment of the invention.

FIG. 9 is a graph illustrating the frequency response characteristics of a transducer assembly according to another embodiment of the invention.

FIG. 10 is a graph illustrating the frequency response characteristics of a transducer assembly according to another embodiment of the invention.

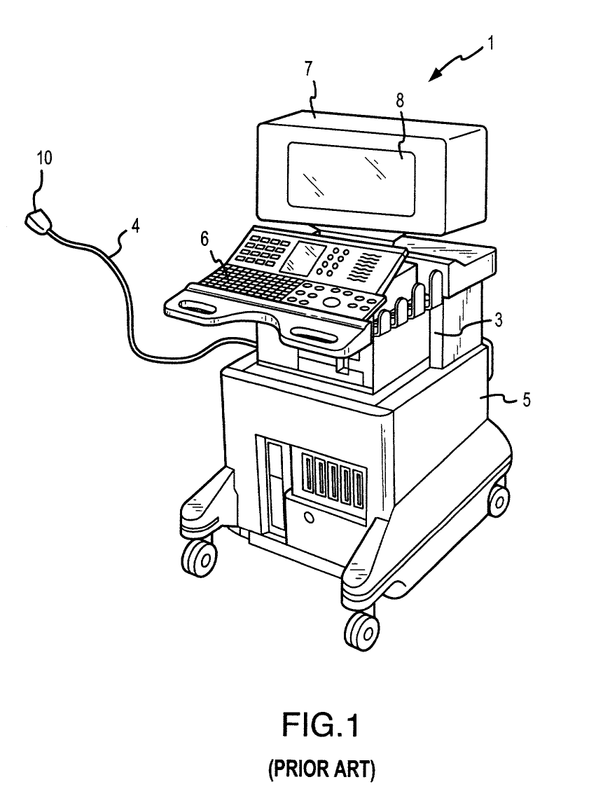

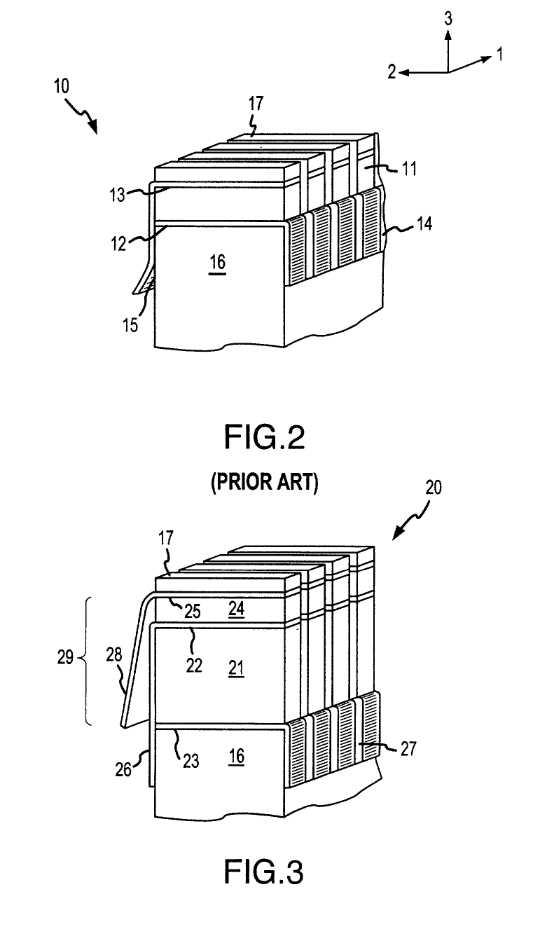

### DETAILED DESCRIPTION OF THE INVENTION

The present invention is generally directed to an apparatus and method for increasing the bandwidth and/or lowering spurious modes of vibration of ultrasound transducers. Many of the specific details of certain embodiments of the invention are set forth in the following description and in FIGS. 3 through 10 to provide a thorough understanding of such embodiments. One skilled in the art will understand, however, that the present invention may be practiced without several of the details described in the following description. Moreover, in the description that follows, it is understood that the figures related to the various embodiments are not to be interpreted as conveying any specific or relative physical dimension, and that specific or relative dimensions related to the various embodiments, if stated, are not to be considered limiting unless the claims expressly state otherwise.

FIG. 3 is a partial isometric view of a transducer assembly 20 according to an embodiment of the invention. The transducer assembly 20 includes a plurality of element stacks 29 positioned on an acoustic backing member 16. For purposes of clarity in the discussion that follows, a single element stack 29 of the assembly 20 will be described in detail. It is understood, however, that the assembly 20 may include a plurality of element stacks 29 that may be arranged in various linear or rectangular arrays, as previously described. Furthermore, such arrangements of element stacks 29 may be planar configurations of the stacks 29, or other shapes, such as arcuate or hemispherical configurations of the stacks 29. The stack 29 includes a first electrode 23 disposed on a lower surface of the stack 29, which abuts the backing member 16. The first electrode 23 establishes a signal coupling to the stack 29, which is further coupled to the ultrasound system (not shown) through a flex circuit 27, although other alternative means for coupling the first electrode 23 to the ultrasound system may be used. A second electrode 25 is disposed on an opposing upper surface of the stack 29 to establish a signal coupling to the stack 29, which may be further coupled to an ultrasound system through a flex coupling 28, although other alternative means for coupling the second electrode 25 to the ultrasound system may be used. An intermediate electrode 22 is interposed between the first electrode 23 and the second electrode 25 to define a first layer 21 that extends between the first electrode 23 and the intermediate electrode 22. The intermediate electrode 22 also defines a second layer 24 that extends between the second electrode 25 and the intermediate electrode 22. The intermediate electrode 22 forms an electrical coupling to the first layer 21 and the second layer 24, which may be further coupled to an ultrasound system through an additional flex circuit 26, although other alternative means for coupling the intermediate electrode 22 to the ultrasound system may be used. The first layer 21 and the second layer 24 may be comprised of a piezoelectric material, such as lead titanate (PT), lead zirconate titanate (PZT) or other suitable alternative piezoelectric materials. The second layer may also be an un-poled piezoelectric material or materials with substantially equivalent sound propagation properties. The first electrode 23, the second electrode 25, and the intermediate electrode 22 may be comprised of a conductive material, such as a layer of gold foil that is adhesively disposed on a surface of the layers 21 and 24. Alternatively, the first electrode 23, the second electrode 25 and the intermediate electrode 22 may be electrodeposited onto surfaces of the layers 21 and 24. The assembly 20 may optionally include one or more impedance matching layers 17 positioned on the second electrode 25 to match the acoustic impedance of the stack 29 to the acoustic impedance of the patient's body.

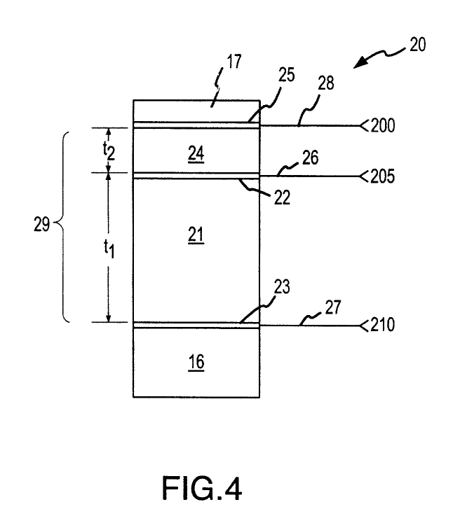

Turning now to FIG. 4, a partial cross-sectional view of the transducer assembly 20 is shown, and will be used to describe the element stack 29 in further detail. As shown, the stack 29 includes the first layer 21 having a thickness of t₁, and the second layer 24 having a thickness of t₂. The thicknesses t₁, and t₂ may be continuously varied to position the intermediate electrode 22 at a variety of different locations within the element stack 29. The first electrode 23 may be coupled to a time-varying excitation signal from an ultrasound system at a location 210, and the second electrode 25 and the intermediate electrode 22 may be coupled together to the ground potential of the ultrasound system, or some other potential, at locations 200 and 205, respectively. If the second layer is an un-poled piezoelectric layer or a material with substantially equivalent sound propagation properties, the second electrode 25 may remain disconnected from the ultrasound system or ground potential. In any case, the frequency response characteristics of the stack 29 may be assessed by examining the calculated impedance magnitude, in absolute terms, produced by the stack 29 when excited at various frequencies. The impedance magnitude will accordingly show a pronounced decrease in the value for the absolute impedance at various frequencies where the element stack 29 achieves a resonant state.

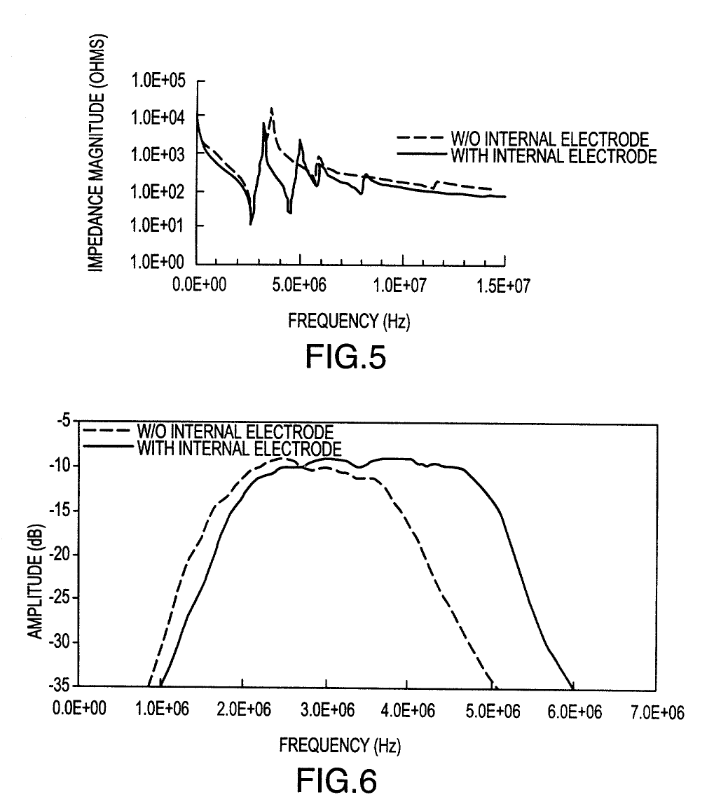

FIG. 5 is a graph illustrating the frequency response characteristics of the element stack 29 of the transducer assembly 20 that is based upon a numerical calculation for an embodiment having a combined thickness (t₁+t₂) of approximately about 0.54 mm and a width of approximately about 0.27 mm. The first layer thickness t₁ is approximately about 60% of the combined thickness of the stack 29. For purposes of comparison, FIG. 5 also shows the calculated impedance magnitude for an element stack that is substantially similar to the stack 29, but without an intermediate electrode 22 positioned within the stack. For both configurations, the fundamental frequency is approximately about 2.8 MHz. As shown in FIG. 5, the addition of the intermediate electrode 22 allows the element stack 29 to resonate at a second harmonic frequency, occurring at approximately about 4.5 MHz, as well as other lateral modes and higher frequencies. In contrast, and referring in particular to the calculated impedance magnitude for the stack that does not contain an intermediate electrode, it is observed that no second order harmonic resonance is present.

Turning now to FIG. 6, a graph illustrating the calculated signal response bandwidth characteristics of the element stack 29, as previously described, is shown. Again, for purposes of comparison, FIG. 6 also shows a calculated bandwidth for an element stack that is substantially similar to the stack 29, but without an intermediate electrode positioned within the stack. With reference to FIG. 6, it is observed that the intermediate electrode 22 substantially increases the bandwidth of the stack 29, as evidenced by the extension of the bandwidth envelope to include higher frequencies without significant signal attenuation. Still further, as noted above, the second harmonic frequency for the stack 29 occurs at approximately about 4.5 MHz. FIG. 6 shows that the sensitivity of the stack 29 having the intermediate electrode 22 is substantially enhanced for this second harmonic frequency. In particular, and with reference still to FIG. 6, it is noted that the calculated signal response bandwidth for a substantially similar stack not having the intermediate electrode exhibits a signal response that is approximately 17 dB lower at the second harmonic frequency than the signal response obtainable from the stack 29.

The foregoing embodiment thus advantageously provides an ultrasound transducer having a bandwidth that is substantially increased in comparison to comparable transducers of conventional design. In particular, the increased bandwidth achievable by the foregoing embodiment allows the transducer to attain improved sensitivity to returning acoustic waves that excite the transducer at second, or even higher order harmonic frequencies.

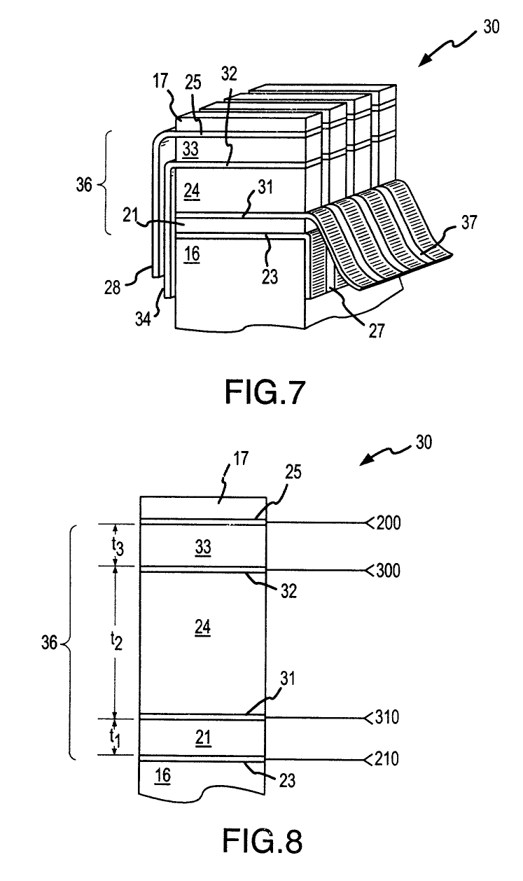

FIG. 7 is a partial isometric view of a transducer assembly 30 according to another embodiment of the invention. The transducer assembly 30 includes a plurality of element stacks 36 positioned on an acoustic backing member 16. Again, for purposes of clarity in the discussion that follows, a single element stack 36 of the assembly 30 will be described in detail. The stack 36 includes a first electrode 23 that is disposed on a lower surface of the stack 36 that abuts the backing member 16. The first electrode 23 establishes a signal coupling to the stack 36, and may be coupled to the ultrasound system (not shown) through a flex circuit 27. A second electrode 25 is disposed on an opposing upper surface of the stack 36. The second electrode 25 similarly establishes a signal coupling to the stack 36, which may also be coupled to the ultrasound system through a flex circuit 28. A first intermediate electrode 31 is interposed between the first electrode 23 and the second electrode 25 to define a first layer 21 that extends between the first electrode 23 and the first intermediate electrode 31. A second intermediate electrode 32 is similarly interposed between the first electrode 23 and the second electrode 25 and defines a second layer 24 that extends between the first intermediate electrode 31 and the second intermediate electrode 32, and further defines a third layer 33 that extends from the second intermediate electrode 32 to the second electrode 25. The first intermediate electrode 31 is electrically coupled to the layers 21 and 24, and may be further coupled to the first electrode 23 and to the ultrasound system through a flex circuit 36 or other connection. In a likewise manner, the second intermediate electrode 32 establishes an electrical coupling to the layers 24 and 33, which may be coupled to the second electrode 25 and to the ultrasound system by a flex circuit 34 or other connection. As in the previous embodiments, the first layer 21, second layer 24 and the third layer 33 may be comprised of any suitable piezoelectric material, such as lead titanate (PT), lead zirconate titanate (PZT) or other alternative materials. Furthermore, the first and third layers may be un-poled piezoelectric material or materials with substantially equivalent sound propagation properties.

Turning now to FIG. 8, a partial cross-sectional view of the transducer assembly 30 is shown, which will be used to describe the element stack 36 in greater detail. The stack 36 includes a first layer 21, a second layer 24, and a third layer 33 that may have first, second and third layer thicknesses t₁, t₂ and t₃, respectively. The first, second and third layer thicknesses may be continuously varied by positioning the first intermediate electrode 32 and the second intermediate electrode 31 at a variety of different locations within the element stack 36. As in a prior embodiment, the first electrode 23 may be coupled to a time-varying excitation signal from an ultrasound system at a location 210, and the second electrode 25 and the second intermediate electrode 32 may be coupled together to the ground potential, or some other potential, of the ultrasound system at locations 200 and 300, respectively. The first intermediate electrode 31 may then be coupled together with the first electrode to the excitation signal from the ultrasound system at a location 310. Alternatively, the second electrode 25 and the second intermediate electrode 32 may be coupled together to the time-varying excitation signal, while the first electrode 23 and the first intermediate electrode 31 are coupled together to the ground potential, or some other potential, of the ultrasound system. As a third alternative, the first electrode 23 and the second electrode 25 may remain disconnected from the ultrasound system or ground potential if the first and third layers are un-poled piezoelectric or equivalent material. In any case, the frequency response characteristics of the stack 36 may again be assessed by examining the calculated impedance magnitude, in absolute terms, produced by the stack 36 when excited at various frequencies. The impedance magnitude will accordingly show a pronounced decrease in the value for the absolute impedance at various frequencies where the element stack 36 achieves a resonant state.

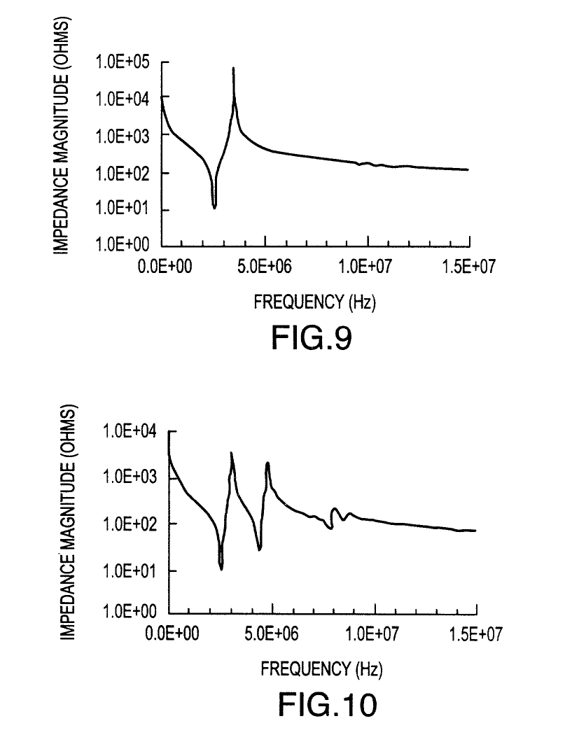

FIG. 9 is a graph illustrating the frequency response characteristics of the element stack 36 that are based upon a numerical calculation for an embodiment having a combined thickness (t₁+t₂+t₃) of approximately about 0.54 mm, and a width of approximately about 0.27 mm. In this embodiment, the first layer thickness t₁ and the third layer thickness t₃ are equal, and are each approximately about 11% of the combined thickness of the stack 36. When the stack 36 is excited, the addition of the first intermediate electrode 31 and the second intermediate electrode 32 allows the stack to resonate at the fundamental frequency, while suppressing resonances at other higher frequencies. For example, as compared to the dashed line in FIG. 5, a resonance corresponding to a third harmonic frequency ordinarily present at approximately about 12 MHz has been suppressed, in addition to a lateral mode that occurs at approximately about 6 MHz.

Turning now to FIG. 10, a graph illustrating the calculated frequency response characteristics of the element stack 36 according to still another embodiment of the invention is shown. In this embodiment, the stack 36 of FIG. 7 has a combined thickness (t₁+t₂+t₃) of approximately about 0.54 mm, and a width of approximately about 0.27 mm. The first layer thickness t₁ is approximately about 11% of the combined thickness, and the third layer thickness t₃ is approximately about 39% of the combined thickness. When the stack 36 is excited, a resonance corresponding to a second harmonic frequency at approximately about 4.5 MHz is produced, similar to the solid line shown in FIG. 5. However, unlike the response characteristic of FIG. 5, the lateral mode resonance at approximately about 6 MHz is suppressed. Accordingly, when the positions of the first intermediate electrode 32 and the second intermediate electrode 31 are varied within the stack 36, the frequency response characteristics of the stack may be varied to either excite higher order harmonic frequencies, or suppress unwanted lateral and higher order modes.

The foregoing embodiment thus allows the frequency response characteristics of an ultrasound transducer to be controlled by positioning the intermediate electrodes at various positions within the transducer. The embodiment thus advantageously permits undesired resonant conditions to be suppressed, yielding a cleaner output signal.

The above description of illustrated embodiments of the invention is not intended to be exhaustive or to limit the invention to the precise form disclosed. While specific embodiments of, and examples of, the invention are described in the foregoing for illustrative purposes, various equivalent modifications are possible within the scope of the invention as those skilled within the relevant art will recognize. Moreover, the various embodiments described above can be combined to provide further embodiments. Accordingly, the invention is not limited by the disclosure, but instead the scope of the invention is to be determined entirely by the following claims.

1. A transducer array of a plurality of transducer stacks in which one of the transducer stacks comprises:
a plurality of piezoelectric layers; and
a plurality of electrodes connected to the piezoelectric layers including a first signal electrode, a second signal electrode, and an intermediate electrode located between two of the piezoelectric layers, the intermediate electrode being coupled to one of the signal electrodes.

2. The transducer array of claim 1 wherein the intermediate electrode is coupled to a reference potential.

3. The transducer array of claim 2 wherein the reference potential is ground potential.

4. The transducer array of claim 1 wherein the intermediate electrode is coupled to an a.c. signal electrode.

5. The transducer array of claim 1 wherein the first electrodes, second electrodes and intermediate electrodes of each stack are comprised of a metallic foil.

6. The transducer array of claim 5 wherein the metallic foil is disposed on the piezoelectric elements of each stack with an adhesive.

7. The transducer array of claim 1 wherein the first electrodes, second electrodes and intermediate electrodes of each stack are comprised of a conductive layer electrodeposited onto the piezoelectric elements.

8. The transducer array of claim 1 wherein the intermediate electrode is separated from the first signal electrode by the thickness of a first piezoelectric layer; the intermediate electrode is separated from the second signal electrode by the thickness of a second piezoelectric layer; and wherein the first and second thicknesses are substantially equal.

9. The transducer array of claim 1 wherein the intermediate electrode is separated from the first signal electrode by the thickness of a first piezoelectric layer; the intermediate electrode is separated from the second signal electrode by the thickness of a second piezoelectric layer; and wherein the first and second thicknesses are unequal.

10. The transducer array of claim 1 wherein an un-poled piezoelectric layer is located between the intermediate electrode and the signal electrode to which the intermediate electrode is coupled.

11. The transducer array of claim 1 wherein the intermediate electrode is coupled to one of the signal electrodes by an unswitched electrical connection.

12. A transducer array of a plurality of transducer stacks in which one of the transducer stacks comprises:
a plurality of piezoelectric layers; and
a plurality of electrodes connected to the piezoelectric layers including a first signal electrode, a second signal electrode, and an intermediate electrode located between two of the piezoelectric layers, one of the signal electrodes being electrically open.

13. The transducer array of claim 12 wherein an un-poled piezoelectric later is located between the intermediate electrode and the signal electrode which is electrically open.

14. The transducer array of claim 13 wherein the intermediate electrode is coupled to a reference potential.

15. The transducer array of claim 13 wherein the intermediate electrode is coupled to an a.c. signal source.

16. A transducer array of a plurality of transducer stacks in which one of the transducer stacks comprises:
a plurality of piezoelectric layers; and
a plurality of electrodes connected to the piezoelectric layers including a first signal electrode, a second signal electrode, a first intermediate electrode located between the signal electrodes and between two of the piezoelectric layers, and a second intermediate electrode located between the signal electrodes and between two of the piezoelectric layers.

17. The transducer array of claim 16 wherein the first intermediate electrode is coupled to one of the signal electrodes.

18. The transducer array of claim 17 wherein the second intermediate electrode is coupled to the other of the signal electrodes.

19. The transducer array of claim 18 wherein one of the signal electrodes is coupled to receive an a.c. signal and the other of the signal electrodes is coupled to a reference potential.

20. The transducer array of claim 16 wherein the first intermediate electrode is separated from the first signal electrode by a piezoelectric layer of a first thickness and the second intermediate electrode is separated from the second signal electrode by a piezoelectric layer of a thickness substantially equal to the first thickness.

21. The transducer array of claim 16 wherein the first intermediate electrode is separated from the first signal electrode by a piezoelectric layer of a first thickness and the second intermediate electrode is separated from the second signal electrode by a piezoelectric layer of a second thickness which is not equal to the first thickness.

22. The transducer array of claim 16 wherein the first signal electrode is electrically open and the intermediate electrode proximate the first signal electrode is coupled to an a.c. signal source or reference potential.

23. The transducer array of claim 22 wherein the second signal electrode is electrically open and the intermediate electrode proximate the second signal electrode is coupled to an a.c. signal source or reference potential.

24. The transducer array of claim 16, wherein one of the piezoelectric layers interposed between an intermediate electrode and a signal electrode comprises an un-poled piezoelectric material.

25. The transducer array of claim 16 wherein each intermediate electrode is coupled to one of the signal electrodes by an unswitched electrical connection.
